(19) United States
(12) Patent Application Publication
(10) Pub. No.: US 2023/0130896 A1
(43) Pub. Date: Apr. 27, 2023

(54) BATTERY CHARGING METHOD AND BATTERY PACK

(71) Applicants: Samsung SDI Co., Ltd., Yongin-si (KR); POSTECH Research and Business Development Foundation, Pohang-si (KR)

(72) Inventors: Jangwoo Lee, Yongin-si (KR); Hyeonjang Pyeon, Pohang-si (KR); Huiyong Chun, Pohang-si (KR); Soohee Han, Pohang-si (KR)

(21) Appl. No.: 18/046,802

(22) Filed: Oct. 14, 2022

Related U.S. Application Data
(60) Provisional application No. 63/262,584, filed on Oct. 15, 2021.

(51) Int. Cl. H02J 7/00; G01R 31/392; G01R 31/367; H01M 10/44; H01M 10/48; H01M 10/42

(52) U.S. Cl. CPC H02J 7/007; G01R 31/367; G01R 31/392; H01M 10/44; H01M 10/425; H01M 10/486; H01M 2010/4271

(57) ABSTRACT

A battery charging method is provided. The battery charging method may include obtaining a reference charging current and a reference lithium dendrite growth rate at the reference charging current, detecting a battery voltage, a battery current, and a battery temperature of a battery in use, based on the battery current, the battery voltage, and the battery temperature, estimating an internal electrochemical parameter of the battery, based on the internal electrochemical parameter, calculating an overpotential steady-state distribution of an active material-electrolyte interface according to a charging current of the battery, based on the overpotential steady-state distribution, calculating a lithium dendrite growth rate according to the charging current of the battery, and based on the reference lithium dendrite growth rate and the lithium dendrite growth rate according to the charging current, determining a charging current value of the battery.

### CROSS-REFERENCE TO RELATED APPLICATION

This application is based on and claims the benefit of U.S. Provisional Pat. Application No. 63/262,584, filed on Oct. 15, 2021, in the United States Patent and Trademark Office, the entire content of which is herein incorporated by reference.

### BACKGROUND

### 1. Field

One or more embodiments relate to a battery charging method and a battery pack, for example, a method of determining a charging current value of a battery based on a lithium dendrite growth rate according to a charging rate of the battery, which is calculated based on internal electrochemical parameters of the battery, and to a battery pack utilizing the method.

### 2. Description of the Related Art

Lithium-ion batteries are actively utilized in various fields, such as energy storage systems and electric vehicles, due to their high energy and power density compared to other types (kinds) of batteries. However, various aging mechanisms occur inside the lithium-ion batteries depending on operating conditions and environmental conditions. These aging mechanisms gradually change the internal state of a battery. Among the various aging mechanisms, the growth of lithium dendrites inside the battery is suggested as the main cause of thermal runaway of the battery. In particular, as the battery ages, a dendrite growth rate accelerates as a result of positive feedback, and accordingly, as the side reaction progresses, the risk of thermal runaway of the battery rapidly increases. Therefore, for safe use of batteries, a method of estimating a lithium dendrite growth rate in real time for various operating characteristics of the battery and a method of controlling the lithium dendrite growth rate at a safe level or less are desired or required.

To estimate an aging rate of the battery in real time and to control the side reaction of the battery, a model for simulating the flux of electrons and lithium inside the battery is desired or required. Accordingly, many models have been proposed to simulate the internal dynamics of lithium-ion batteries. Most techniques are based on non-physicochemical models, such as an equivalent circuit model (ECM) or other empirical models with relatively simple structures using several parameters. This type or kind of model has a low computational burden and may be simply applied, but the model mainly refers to the resistance and impedance of the entire battery, and does not perform simulations based on characteristics of each internal material, and thus it shows limitations in accuracy and expressive power.

Some studies have achieved more accurate estimates by utilizing sophisticated electrochemical lithium-ion battery models based on physicochemical properties of each battery material, such as an active material and/or an electrolyte. However, although electrochemical models may represent various aging states of the battery, it is difficult to put into practice real-time estimation and control of the aging rate of the battery due to the large amount of computation.

### SUMMARY

Aspects of one or more embodiments of the present disclosure are directed towards addressing the problems described above, and towards providing a method and a battery pack using the same, the method including estimating a lithium dendrite growth rate according to a charging rate of a battery based on an internal electrochemical parameter of the battery in use, determining a charging current value of the battery based on the lithium dendrite growth rate, and charging the battery based on the charging current value.

Additional aspects will be set forth in part in the description which follows and, in part, will be apparent from the description, or may be learned by practice of the presented embodiments of the disclosure.

One or more embodiments of the present disclosure include a battery charging method that is performed by a computing apparatus including at least one processor. The battery charging method may include obtaining a reference charging current and a reference lithium dendrite growth rate at the reference charging current, detecting a battery voltage, a battery current, and a battery temperature of a battery in use, based on the battery current, the battery voltage, and the battery temperature, estimating an internal electrochemical parameter of the battery, based on the internal electrochemical parameter, calculating an overpotential steady-state distribution of an active material-electrolyte interface according to a charging current of the battery, based on the overpotential steady-state distribution, calculating a lithium dendrite growth rate according to the charging current of the battery, and based on the reference lithium dendrite growth rate and the lithium dendrite growth rate according to the charging current, determining a charging current value of the battery.

One or more embodiments of the present disclosure include a battery pack including a battery, a sensor configured to detect a battery current, a battery voltage, and a battery temperature of the battery, and a battery management unit including a memory and at least one processor to manage the battery. The memory may store a reference charging current, a reference lithium dendrite growth rate at the reference charging current, and a physical property value of the battery. The processor may be configured to, based on the battery current, the battery voltage, and the battery temperature, estimate an internal electrochemical parameter of the battery, based on the physical property value and the internal electrochemical parameter of the battery, calculate an overpotential steady-state distribution of an active material-electrolyte interface according to a charging current of the battery, based on the overpotential steady-state distribution, calculate a lithium dendrite growth rate according to the charging current of the battery, and based on the reference lithium dendrite growth rate and the lithium dendrite growth rate according to the charging current, determine a charging current value of the battery.

A computer program according to an embodiment is stored in a medium to execute the aforementioned battery charging method on the computing apparatus.

### BRIEF DESCRIPTION OF THE DRAWINGS

The above and other aspects, features, and/or principles of certain embodiments of the present disclosure will be more apparent from the following description taken in conjunction with the accompanying drawings, in which:

FIG. 1 illustrates a schematic diagram of a battery pack according to one or more embodiments of the present disclosure;

FIG. 2 illustrates a schematic diagram of an internal configuration of a battery management unit, according to one or more embodiments of the present disclosure;

FIG. 3 illustrates a schematic diagram of an internal configuration of a processor, according to one or more embodiments of the present disclosure;

FIG. 4 illustrates a conceptual diagram of a lithium-ion battery according to one or more embodiments of the present disclosure;

FIG. 5 illustrates a conceptual diagram of an overpotential distribution according to one or more embodiments of the present disclosure;

FIG. 6A illustrates a chart of aging conditions of batteries according to one or more embodiments of the present disclosure;

FIG. 6B illustrates a chart of estimates of overpotential coefficients according to one or more embodiments of the present disclosure; and

FIG. 6C illustrates a chart of ratios of overpotential coefficients according to one or more embodiments of the present disclosure.

### DETAILED DESCRIPTION

Reference will now be made in more detail to embodiments, examples of which are illustrated in the accompanying drawings, wherein like reference numerals refer to like elements throughout, and duplicative descriptions thereof may not be provided. In this regard, the present embodiments may have different forms and should not be construed as being limited to the descriptions set forth herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

Further, the embodiments are merely described below, by referring to the drawings, to explain aspects of the present description. As used herein, the term “and/or” includes any and all combinations of one or more of the associated listed items. Expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from a, b, and c,” “at least one from among a, b, and c,” “one from among a, b, and c”, “at least one of a to c” indicates only a, only b, only c, both a and b, both a and c, both b and c, all of a, b, and c, or variations thereof.

Hereinafter, various embodiments will be described in more detail with reference to the accompanying drawings such that one of ordinary skill in the art may easily implement the disclosure. However, because the technical spirit of the disclosure may be modified and implemented in various forms, the disclosure is not limited to embodiments described herein. In the description of the embodiments disclosed herein, when it is determined that a detailed description of a related known technology may obscure the gist of the disclosure, a detailed description of the known technology may not be provided. Like reference numerals refer to the same or similar elements, and a detailed description thereof may not be provided.

As described herein, when an element is “connected” to another element, the element may not only be “directly connected” to the other element, but may also be “electrically connected” to the other element with another element in between. In addition, when an element “includes” another element, it means that the element may further include another element in addition to the other element instead of excluding another element, unless otherwise stated. In addition, it will also be understood that when an element or layer is referred to as being “between” two elements or layers, it can be the only element or layer between the two elements or layers, or one or more intervening elements or layers may also be present.

Some embodiments may be described in terms of functional block elements and various processing steps. Some or all of the functional blocks may be implemented by various numbers of hardware and/or software elements for performing particular functions. For example, the functional blocks of the disclosure may be implemented by one or more microprocessors or by circuit elements for a certain function. The functional blocks of the disclosure may be implemented in various programming or scripting languages. The functional blocks of the disclosure may be implemented in an algorithm executed by one or more processors. Functions performed by the functional blocks of the disclosure may be performed by a plurality of functional blocks, or functions performed by a plurality of functional blocks in the disclosure may be performed by one functional block. In addition, the disclosure may employ general techniques for electronic environment setting, signal processing, and/or data processing.

An overpotential distribution of a lithium-ion battery indicates how much force is applied to lithium ions to cause the lithium ions to cross an active material-electrolyte interface. Therefore, the overpotential distribution serves as activation energy of chemical side reactions in which lithium ions react, such as solid electrolyte interphase (SEI) layer growth and lithium dendrite growth occurring at an interface, and determines whether a side reaction occurs, and a rate of the side reaction. In addition, an interfacial side reaction is the main cause of lithium loss. Accordingly, predictions regarding side reactions in the lithium-ion battery may be achieved through more precise calculation of the overpotential distribution.

In general, the flow dynamics of electrons and lithium ions inside the lithium-ion battery is defined as a combination of four partial differential equations and a Butler-Volmer equation that combine them. Each equation defines the flux distribution of lithium ions and electrons in an active material and an electrolyte. Accordingly, a value of a general overpotential distribution is calculated as a numerical value of the partial differential equations.

The calculation of a numerical solution of the lithium-ion battery dynamics requires a lot of memory space and computational power. However, commercial battery management systems do not have memory and computational power to process the calculation in real time. This makes it difficult to develop a real-time battery prediction program and apparatus. For example, to calculate a one-dimensional finite difference-based battery numerical analysis model based on a 12-bit decimal floating point calculation, memory of at least 11 MB is required. However, Ecotron’s EV2274A board, one of the embedded boards for commercial battery management systems, has only memory of 384 kB.

To overcome this limitation, a volume-averaged lithium-ion battery model has been proposed. The volume-averaged lithium-ion battery model is able to calculate the electrochemical numerical value of the lithium-ion battery utilizing memory of about 65 kB by volume-leveling and calculating a potential and lithium concentration in the electrolyte and the active material.

However, an overpotential of the lithium-ion battery has a different value at each position depending on the proximity to a separator or a collector inside a battery. Furthermore, different overpotential values for respective positions cause different aging patterns. When a high overpotential occurs near the separator in an anode region, the growth of lithium dendrites accelerates, which may cause damage to the separator. When the separator is excessively damaged and is not able to function, the lithium dendrites generates a short circuit that connects a cathode and an anode, which may generate heat and cause thermal runaway of the battery. In contrast, when a high overpotential occurs near the current collector in a cathode region, a crystal structure of a cathode material is deformed by excessive physical stress generated when lithium ions pass through an interface. Therefore, this reduces a contact surface between the current collector and the cathode material and increases effective resistance, and thus reduces power of the battery and increases an amount of heat generated. In conclusion, a high overpotential distribution causes thermal runaway depending on the position thereof or serves as a cause of other aging patterns, such as drop of battery power.

In the case of a volume-averaged model, a voltage in each region is volume-leveled as a single value rather than a distribution, and thus, it is impossible to calculate the overpotential distribution. Therefore, the volume-averaged model may be utilized for estimating the state of an electrochemical parameter, but may not be utilized for predicting.

One or more embodiments of the present disclosure adopt a different approach from the volume-averaging method for predictions regarding the lithium-ion battery. According to embodiments of the present disclosure, a distribution that is not a volume-averaged single value is calculated, but a steady-state solution, not a transient-state solution, of an overpotential is calculated to reduce an amount of computation and memory. According to one or more embodiments of the present disclosure, an overpotential distribution of each region inside the battery may be calculated, and accordingly, it may be predicted whether a side reaction of the battery will accelerate or decelerate in the future.

In order to solve a problem that there is a large amount of computation of a transient-state solution while maintaining the governing equations and boundary conditions of an electrochemical model, one or more embodiments provide a method of estimating an lithium dendrite growth rate in real time through a calculation of a steady state solution of an overpotential distribution, which is a spatial value of an equilibrium point, except for a time axis calculation, determining a charging current value of a battery based on the lithium dendrite growth rate, and charging the battery by utilizing the charging current value.

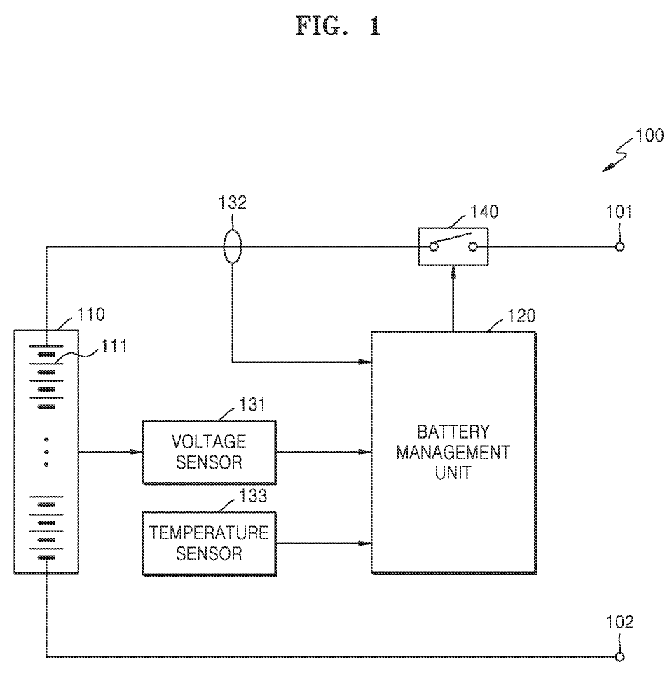

FIG. 1 illustrates a schematic diagram of a battery pack 100 according to one or more embodiments of the present disclosure.

Referring to FIG. 1, the battery pack 100 may include a battery 110, a battery management unit 120, sensors 131, 132, and 133, and a switch 140.

The battery 110 may include at least one battery cell 111, and the battery cell 111 may be a rechargeable secondary battery. For example, the battery cell 111 may be a lithium-ion battery.

The number and connection method of battery cells 111 constituting the battery 110 may be determined based on an amount of power and voltage required for the battery pack 100. Although FIG. 1 illustrates for illustrative purposes only that the battery cells 111 included in the battery 110 are connected to each other in series, the battery cells 111 may be connected to each other in parallel or in series and in parallel. FIG. 1 illustrates for illustrative purpose only that the battery pack 100 includes one battery 110, but the battery pack 100 may include a plurality of batteries 110 connected to each other in series, in parallel, or in series and in parallel.

The battery 110 may include a plurality of battery modules each including a plurality of battery cells 111. The battery pack 100 includes pack terminals 101 and 102 to which an electric load or a charging apparatus may be connected. The battery 110 utilized herein refers to a battery in use that supplies electric energy to the electric load or receives electric energy from the charging apparatus. In the specification, a new battery distinguished from the battery 110 in use is the same type or kind of battery as the battery 110, and refers to a battery immediately after being manufactured. A state of health (SOH) of the new battery is 1, and a SOH of the battery 110 is less than 1.

In one or more embodiments, an object for determining a charging current value may be the battery 110, or may be each of the battery cells 111 included in the battery 110. In one or more embodiments, a method of determining a charging current value of the battery 110 is described as an example, but the same description may also be applied to a method of determining a charging current value of each of the plurality of battery cells 111 included in the battery 110.

In one or more embodiments, the charging current value does not refer to a magnitude of a charging current actually utilized to charge the battery 110, but refers to an appropriate or suitable charging current value of the battery 110 for preventing or reducing rapid aging of the battery 110. When the battery 110 is charged with the charging current value determined according to one or more embodiments of the present disclosure, the battery 110 may age to the same level as compared to when being charged with a reference charging current at a reference temperature.

The switch 140 is connected between the battery 110 and one (e.g., 101) of the pack terminals 101 and 102. The switch 140 may be controlled by the battery management unit 120.

The battery management unit 120 may manage the battery 110. The battery management unit 120 may manage a charging state, a charging/discharge current, etc. of the battery 110. The battery management unit 120 may detect a battery voltage of the battery 110 by utilizing a voltage sensor 131, detect a battery current, e.g., a charging current and a discharging current, of the battery 110 by utilizing a current sensor 132, and measure a battery temperature of the battery 110 by utilizing a temperature sensor 133.

The battery management unit 120 may also detect a cell voltage of each of the battery cells 111 included in the battery 110 by utilizing the voltage sensor 131. The battery management unit 120 may also equalize cell voltages of the battery cells 111. When the battery 110 is overcharged, overdischarged, or in a high temperature state, the battery management unit 120 may detect the state and open the switch 140.

The battery management unit 120 may estimate an internal electrochemical parameter (or internal electrochemical parameters) of the battery 110 by utilizing the battery voltage, the battery current, and the battery temperature, calculate an overpotential steady-state distribution of an active material-electrolyte interface according to the charging current of the battery 110 based on the internal electrochemical parameter(s), calculate a lithium dendrite growth rate according to the charging current of the battery 110 based on the overpotential steady-state distribution, and determine a charging current value of the battery 110 based on a reference lithium dendrite growth rate and the lithium dendrite growth rate according to the charging current. A method by which the battery management unit 120 determines the charging current value of the battery 110 is now described in more detail.

The battery management unit 120 may be to transmit the charging current value of the battery 110 to the charging apparatus. According to one or more embodiments, the charging apparatus may supply, to the battery pack 100, a charging current having a magnitude corresponding to the received charging current value. According to one or more embodiments, the battery management unit 120 may be to transmit, to the charging apparatus, the charging current value of the battery 110 as a charging current limit value. The charging apparatus may supply, to the battery pack 100, a charging current having a magnitude less than or equal to the charging current limit value.

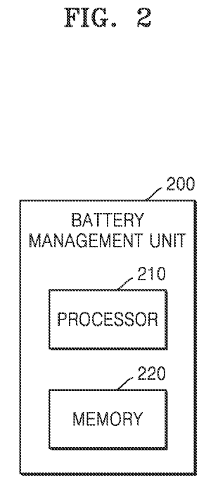

FIG. 2 illustrates a schematic diagram of an internal configuration of a battery management unit 200, according to one or more embodiments of the present disclosure.

Referring to FIG. 2, the battery management unit 200 includes a processor 210 and a memory 220. The battery management unit 200 may correspond to the battery management unit 120 of FIG. 1.

The processor 210 controls overall operations of the battery management unit 200. The processor 210 may perform basic arithmetic, logic, and input/output operations, and execute, e.g., program code stored in the memory 220, e.g., a pre-trained artificial neural network. The processor 210 may store data in the memory 220 or load data stored in the memory 220.

The memory 220 is a recording medium readable by the processor 210 and may include random access memory (RAM), read-only memory (ROM), etc. The memory 220 may store an operating system and a program or application code for executing the battery charging method according to one or more embodiment embodiments. The memory 220 may store a reference lithium dendrite growth rate at a reference charging current of a new battery. The memory 220 may store a physical property value (or physical property values) of the battery 110. For example, the memory 220 may store, as physical property values of the battery 110, a thickness L of a battery layer including a cathode material, a separator, and an anode material of the battery 110, a thickness ratio Iₚ of the cathode material in the battery layer, a thickness ratio Iₙ of the anode material in the battery layer, a thickness ratio Iₛ of the separator in the battery layer, a Bruggeman coefficient B_{a,i} of an active material of a region i, a Bruggeman coefficient B_{e,i} of an electrolyte of the region i, and an area A of the battery layer. In this case, i denotes an internal region of the battery 110, when i is p, i denotes a cathode region, when i denotes s, i denotes a separator region, and when i denotes n, i denotes an anode region. The physical property value(s) of the battery 110 and physical property value(s) of the new battery may be equal to each other.

The memory 220 may store program code for estimating an internal electrochemical parameter (or internal electrochemical parameters) of the battery 110 from a battery voltage, a battery current, and a battery temperature of the battery 110 in use. The memory 220 may store an artificial neural network for estimating an internal electrochemical parameter (or internal electrochemical parameters) of the battery 110 from the battery voltage, the battery current, and the battery temperature.

According to one or more embodiments, the memory 220 may store an overpotential steady-state distribution of an active material-electrolyte interface of the new battery according to a reference charging rate of the new battery, an internal electrochemical parameter (or internal electrochemical parameters) of the new battery, and a reference charging current.

The processor 210 may be configured to, by utilizing the voltage sensor 131, the current sensor 132, and the temperature sensor 133, detect a battery current, a battery voltage, and a battery temperature of the battery 110, respectively, estimate an internal electrochemical parameter (or internal electrochemical parameters) of the battery 110 based on the battery voltage, the battery current, and the battery temperature, calculate an overpotential steady-state distribution of the active material-electrolyte interface according to a charging current of the battery 110 based on the physical property value(s) of the battery 110 stored in the memory 220 and the internal electrochemical parameter(s) of the battery 110, calculate a lithium dendrite growth rate according to the charging current of the battery 110 based on the overpotential steady-state distribution, and determine a charging current value of the battery 110 based on the reference lithium dendrite growth rate stored in the memory 220 and the lithium dendrite growth rate according to the charging current. The processor 210 may cause a charging current having a magnitude corresponding to the charging current value to be supplied to the battery pack 100 by transmitting the charging current value to an external apparatus, such as a charging apparatus or an integrated controller.

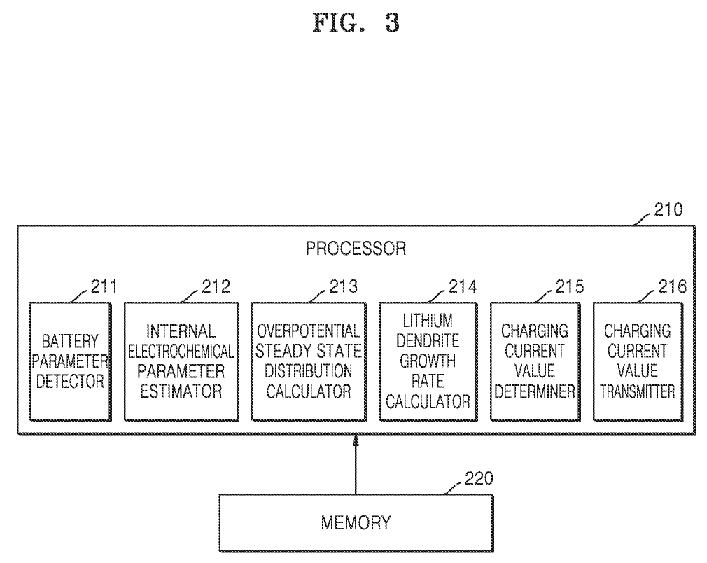

FIG. 3 illustrates a schematic diagram of an internal configuration of the processor 210, according to one or more embodiments.

Referring to FIG. 3, the processor 210 includes a battery parameter detector 211, an internal electrochemical parameter estimator 212, an overpotential steady-state distribution calculator 213, a lithium dendrite growth rate calculator 214, and a charging current value determiner 215. The processor 210 may further include a charging current value transmitter 216.

The battery parameter detector 211 may detect a battery voltage, a battery current, and a battery temperature of the battery 110 by utilizing the voltage sensor 131, the current sensor 132, and the temperature sensor 133, respectively.

The internal electrochemical parameter estimator 212 may estimate an internal electrochemical parameter (or internal electrochemical parameters) of the battery 110 based on the battery current, battery voltage, and battery temperature detected by the battery parameter detector 211.

The internal electrochemical parameter estimator 212 may have an artificial neural network (or artificial neural network circuits) for estimating the internal electrochemical parameter(s) of the battery 110 based on the battery current, the battery voltage, and the battery temperature of the battery 110. When battery current time series data, battery voltage time series data, and battery temperature time series data are input to the artificial neural network, the artificial neural network may output the internal electrochemical parameter(s) of the battery 110.

The artificial neural network may be pre-trained using pieces of training data generated by utilizing a battery electrochemical model. When a battery current is input to a battery while changing a battery temperature and parameters of the battery electrochemical model, a battery voltage may be obtained as a response thereof.

The internal electrochemical parameter estimator 212 may be implemented with reference to, e.g., the article, Jungsoo Kim, Huiyong Chun, Minho Kim, Soohee Han, Jang-Woo Lee, and Tae-Kyung Lee, Effective and practical parameters of electrochemical Li-ion battery models for degradation diagnosis, Journal of Energy Storage, Volume 42, 2021, the entire content of which is herein incorporated by reference.

The artificial neural network may output the internal electrochemical parameter(s) including an area per volume aₚ of a cathode active material-electrolyte interface of the battery 110, an area per volume aₙ of an anode active material-electrolyte interface of the battery 110, an electrical conductivity σ_{a,i}(T) of an active material according to the battery temperature, an ionic conductivity σₑ(T) of an electrolyte according to the battery temperature, a porosity εᵢ of the electrolyte in a region i, a lithium ion transport rate

$${\text{t}}_{+}^{0}$$

of the electrolyte, an initial concentration C_{e,0} of lithium ions in the electrolyte, and a diffusion coefficient Dₑ(T) of lithium ions in the electrolyte according to the battery temperature. In this case, i denotes the internal region of the battery 110, when i is p, i denotes the cathode region, when i denotes s, i denotes the separator region, and when i denotes n, i denotes the anode region.

The internal electrochemical parameter(s) of the battery 110, which is(are) estimated by the internal electrochemical parameter estimator 212, may further include at least one of the initial concentration C_{e,0} of lithium ions in the electrolyte, a lithium diffusion coefficient Dₚ(T) of the cathode material according to the battery temperature, a lithium diffusion coefficient Dₙ(T) of the anode material according to the battery temperature, an electrical conductivity σₚ(T) of the cathode material according to the battery temperature, an electrical conductivity σₙ(T) of the anode material according to the battery temperature, a Butler-Volmer rate constant kₚ for the cathode material, a Butler-Volmer rate constant kₙ for the anode material, a lithium dendrite growth reaction rate constant kₛ, an SEI layer resistance R_{SEI}, a maximum lithium stoichiometry θ_{p,max} of the cathode material, a maximum lithium stoichiometry θ_{n,max} of the anode material, a minimum lithium stoichiometry θ_{p,min} of the cathode material, and a minimum lithium stoichiometry θ_{n,min} of the anode material.

The overpotential steady-state distribution calculator 213 may calculate the overpotential steady-state distribution of the active material-electrolyte interface according to the charging current of the battery 110 based on the physical property value(s) of the battery 110 stored in the memory 220 and the internal electrochemical parameter(s) of the battery 110, which is(are) estimated by the internal electrochemical parameter estimator 212. The active material may collectively refer to a cathode active material and an anode active material.

According to one or more embodiments, the overpotential steady-state distribution calculator 213 may calculate the overpotential steady-state distribution of the active material-electrolyte interface according to the charging current of the battery 110 by utilizing a differential equation and a boundary condition equation, based on the physical property values, the internal electrochemical parameters, and the battery temperature of the battery 110.

$$\frac{\partial {η}_{i} \left(X\right)}{\partial X} = {i}_{a p p} \left({\text{k}}_{a , i} \left(θ\right) \frac{{\text{f}}_{i} \left(\text{X}\right)}{{\text{l}}_{i}} - {\text{k}}_{e , i} \left(θ\right) \frac{{\text{l}}_{i} - {\text{f}}_{i} \left(\text{X}\right)}{{\text{l}}_{i}}\right) - \frac{\partial {U}_{i} \left(X\right)}{\partial X}$$

$${Φ}_{n} \left(\text{X = 1}\right) = 0 , {\int }_{{Ω}_{i}} \text{sinh} \left(\frac{F}{2 R T} {η}_{i} \left(X\right)\right) d X = \frac{{i}_{a p p}}{2 A F {\text{l}}_{i} {a}_{i} {i}_{0}}$$

In this case, i denotes the internal region of the battery 110, and when i is p, i denotes the cathode region, when i denotes s, i denotes the separator region, and when i denotes n, i denotes the anode region. X is a dimensionless position of the battery 110, when X is 0, X denotes a cathode tip of the battery 110, and when X is 1, X denotes an anode tip of the battery 110. L denotes a thickness of one battery layer including a cathode material, a separator, and an anode material of the battery 110. ηᵢ(X) denotes an overpotential between the active material and the electrolyte at X of the region i. iₐₚₚ denotes a magnitude of a current density applied to a unit area of the battery layer in response to a charging current. Uᵢ is an open circuit potential of the active material in the region i. lᵢ is a thickness ratio of the region i to the battery layer, lₚ is a thickness ratio of the cathode material in the battery layer, lₙ is a thickness ratio of the anode material in the battery layer, and lₛ is a thickness ratio of the separator in the battery layer.

$${\text{f}}_{i} \left(\text{X}\right) \text{is a function defined as} \left\{\begin{matrix}{\text{l}}_{p} - X i = p \\ 0 i = s \\ X - \left(1 - {\text{l}}_{n}\right) i = n\end{matrix}\right) ⋅$$

k_{a,i}(θ) is an overpotential coefficient of the active material in the region i, which determines an open form of an overpotential distribution calculated from the physical property value(s), the internal electrochemical parameter(s), and the battery temperature of the battery 110, k_{e,i}(θ) is an overpotential coefficient of the electrolyte in the region i, which determines the open form of the overpotential distribution calculated from the physical property value(s), the internal electrochemical parameter(s), and the battery temperature of the battery 110, and θ is a battery parameter including the physical property value(s), the internal electrochemical parameter(s), and the battery temperature of the battery 110.

Φₙ(X = 1) is a voltage of an anode tip of the battery 110. Ωᵢ denotes a range of values of X in the region i. F is a Faraday constant, R is a gas constant, and T is the battery temperature. aᵢ is an area per volume of the active material-electrolyte interface of the region i, aₚ is an area per volume of the cathode active material-electrolyte interface, and aₙ is an area per volume of the anode active material-electrolyte interface. i₀ is a Butler-Volmer exchange current density between the electrolyte and the active material of the battery 110.

The overpotential coefficient k_{a,i}(θ) of the active material in the region i may be calculated according to

$${k}_{a , i} \left(θ\right) = \frac{\text{L}}{{σ}_{a , i} \left(T\right) {\left(1 - {ε}_{i}\right)}^{{B}_{a , i}}} .$$

The overpotential coefficient k_{e,i}(θ) of the electrolyte in the region i may be calculated according to

$${k}_{e , i} \left(θ\right) = \frac{\text{L}}{{ε}_{i} {}^{{B}_{e , i}}} \left(\frac{1}{σ e \left(T\right)} + \frac{2 {\left(1 - {t}_{+}^{0}\right)}^{2} R T}{{F}^{2} {C}_{e , 0} {D}_{e} \left(T\right)}\right) .$$

In this case, σ_{a,i}(T) denotes an electrical conductivity of the active material according to the battery temperature. εᵢ is a porosity of the electrolyte in the region i, B_{a,i} is a Bruggeman coefficient of the active material in the region i, and B_{e,i} is a Bruggeman coefficient of the electrolyte in the region i. σₑ(T) denotes an ionic conductivity of the electrolyte according to the battery temperature.

$${t}_{+}^{0}$$

denotes a lithium ion transport rate of the electrolyte, C_{e,0} denotes an initial concentration of lithium ions in the electrolyte, and Dₑ(T) denotes a diffusion coefficient of lithium ions in the electrolyte according to the battery temperature.

The overpotential steady-state distribution calculator 213 may solve the differential equation under the boundary condition equation by utilizing at least one numerical analysis method among a finite difference method, a finite element method, and/or a finite volume method. The overpotential distribution calculator 213 may calculate an approximate value of the overpotential steady-state distribution ɳᵢ (X) in the active material-electrolyte interface according to the charging current of the battery 110 by utilizing an approximate expression.

The lithium dendrite growth rate calculator 214 may calculate the lithium dendrite growth rate according to the charging current of the battery 110 based on the overpotential steady-state distribution calculated by the overpotential steady-state distribution calculator 213.

According to one or more embodiments, the lithium dendrite growth rate calculator 214 may calculate the lithium dendrite growth rate according to the charging current of the battery 110 by utilizing

$${j}_{s} = - \frac{{i}_{o , s}}{F} exp \left(- \frac{{α}_{s} F}{R T} η \left(X\right)\right)$$

based on the overpotential steady-state distribution.

In this case, jₛ denotes the lithium dendrite growth rate, i_{0,s} denotes an exchange current density of a chemical reaction of lithium dendrite growth, F is the Faraday constant, R denotes the gas constant, T denotes the battery temperature, αₛ denotes a charge transfer coefficient of a lithium dendrite growth reaction, X denotes the dimensionless position of the battery 110, and ɳ(X) is an overpotential at X of the battery 110, indicating the overpotential steady-state distribution.

The charging current value determiner 215 may determine the charging current value of the battery 110 based on the reference lithium dendrite growth rate stored in the memory 220 and the lithium dendrite growth rate according to the charging current of the battery 110, which is calculated by the lithium dendrite growth rate calculator 214.

According to one or more embodiments, the charging current value determiner 215 may determine the charging current value of the battery 110 based on a value of a charging current at which the lithium dendrite growth rate according to the charging current of the battery 110 is equal to the reference lithium dendrite growth rate.

According to one or more embodiments, the charging current value determiner 215 may determine the charging current value of the battery 110 based on a ratio of the lithium dendrite growth rate according to the charging current of the battery 110 to the reference lithium dendrite growth rate.

The ratio of the lithium dendrite growth rate according to the charging current of the battery 110 to the reference lithium dendrite growth rate may be defined by

$$\text{r} \left(\text{X}\right) = exp \left(\frac{{α}_{\text{s}} \text{F}}{\text{R}} \left(\frac{{η}_{\text{MOL}} \left(\text{X} \left|{\text{i}}_{\text{MOL}}\right)\right)}{{\text{T}}_{\text{MOL}}} - \frac{{η}_{\text{BOL}} \left(\left(\text{X}\right| {\text{i}}_{\text{BOL}}\right)}{{\text{T}}_{\text{BOL}}}\right)\right) ⋅$$

In this case, X denotes the dimensionless position of the battery 110, r(X) is a ratio of the lithium dendrite growth rate at X of the battery 110, αₛ is the charge transfer coefficient of the lithium dendrite growth reaction, F is the Faraday constant, R is the gas constant, i_{BOL} is a current density of the reference charging current, i_{MOL} is a current density of the charging current of the battery 110, ɳ_{BOL} is an overpotential steady-state distribution of an active material-electrolyte interface of a new battery, ɳ_{MOL} is an overpotential steady-state distribution of the battery 110, T_{BOL} is a reference temperature, and T_{MOL} is the battery temperature. The current density i_{BOL} of the reference charging current, the overpotential steady-state distribution ɳ_{BOL} of the active material-electrolyte interface of the new battery, and the reference temperature T_{BOL} may be stored in advance in the memory 220.

The charging current value determiner 215 may determine the charging current value of the battery 110 based on i_{MOL} satisfying

$$\frac{{η}_{\text{MOL}} \left(\text{X} \left|{\text{i}}_{\text{MOL}}\right)\right)}{{\text{T}}_{\text{MOL}}} - \frac{{η}_{\text{BOL}} \left(\left(\text{X}\right| {\text{i}}_{\text{BOL}}\right)}{{\text{T}}_{\text{BOL}}} .$$

A reference lithium dendrite growth rate according to a reference charging current of the new battery may be stored in advance in the memory 220. The processor 210 may obtain the reference charging current of the new battery. The reference charging current of the new battery may be stored in advance in the memory 220. According to another example, the processor 210 may also obtain the reference charging current by calculating the reference charging current based on a physical property value (or physical property values) of the new battery.

The processor 210 may estimate an internal electrochemical parameter (or internal electrochemical parameters) of the new battery by utilizing the internal electrochemical parameter estimator 212. The processor 210 may calculate an overpotential steady-state distribution of an active material-electrolyte interface of the new battery according to the reference charging current by utilizing the overpotential steady-state distribution calculator 213. The processor 210 may calculate a reference lithium dendrite growth rate at the reference charging current of the new battery based on the overpotential steady-state distribution of the active material-electrolyte interface of the new battery by utilizing the lithium dendrite growth rate calculator 214. The reference temperature may be stored in advance in the memory 220, and the processor 210 may utilize the reference temperature to estimate the internal electrochemical parameter(s) of the new battery, calculate the overpotential steady-state distribution of the active material-electrolyte interface of the new battery, or calculate the reference lithium dendrite growth rate at the reference charging current of the new battery.

Symbols used herein, their associated units, and descriptions thereof are as follows.

| | | |
|---|---|---|
| Symbol | Unit | Description |
| i | [-] | Subscript for internal regions of battery p: cathode, s: separator, and n: anode |
| B | [-] | Bruggeman coefficient for each region |
| Cₑ,₀ | [mol/m³] | Initial concentration of lithium ions in electrolyte |
| C_{e,i} | [mol/m³] | Concentration of lithium ions in electrolyte of region i |
| D_{a,i} | [m²/s] | Diffusion coefficient of lithium in active material of region i |
| Dₑ | m²/s] | Diffusion coefficient of lithium ions in electrolyte |
| D_{eƒƒ} | m²/s] | Effective diffusion coefficient |
| F | [C/mol] | Faraday constant |
| 1_{0,s} | [A/m²] | Exchange current density of chemical reaction of lithium dendrite growth |
| iₐₚₚ | [A/m²] | Current density applied to battery layer in response to charging current |
| i_{a,i} | [A/m²] | Current density in active material of region i |
| jₛ | [mol/m²s] | Flux density of side reaction positive charge in orthogonal direction outside surface of active material |
| kₐ,ᵢ | [m²/S] | Overpotential coefficient of active material of region i |
| k_{e,i} | [m²/S] | Overpotential coefficient of electrolyte of region i |
| lᵢ | [-] | Dimensionless domain length of region i |
| L | [m] | Thickness of single battery layer |
| N_{a,i} | [mol/m²s] | Lithium flux density in active material of region i |
| Nₑ | [mol/m²s] | Lithium ions flux density in electrolyte |
| p | [-] | Dimensionless starting position of separator |
| q | [-] | Dimensionless starting position of anode material |
| R | [J/K^{.}mol) | Gas constant |
| T | [K] | Temperature |
| | [-] | Lithium ion transport rate of electrolyte |
| V_{battery} | [V] | voltage of lithium-ion battery cell |
| x | [m] | Position |
| Xᵢ | [m] | Starting position of region i |
| X | [-] | Dimensionless position |
| αₛ | [-] | Side reaction asymmetric charge-transfer coefficient, 0.5 |
| εᵢ | [-] [-] | Electrolyte porosity in region i |
| ɳᵢ | [V] | Overpotential distribution in region i |
| ɳₛ | [V] | Side reaction overpotential |
| σ_{a,i} | [S/m] | Conductivity of active material in region i |
| σₑ | [S/m] | Electrolyte conductivity |
| σ_{eƒƒ} | [S/m] | Effective conductivity |
| Φ_{a,i} | [V] | Potential of active material in region i |
| Φ_{e,i} | [V] | Potential of active material in region i |

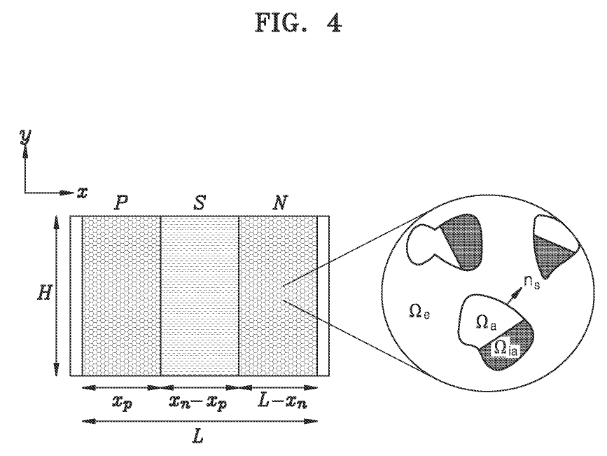

FIG. 4 illustrates a conceptual diagram of a lithium-ion battery according to one or more embodiments of the present disclosure.

Governing equations for the lithium-ion battery are as shown in Equations 1 to 4.

$${i}_{a , i} = - {σ}_{a , e f f} ∇ {ϕ}_{a , i} \text{x} ∈ {Ω}_{a}$$

$${\text{N}}_{a , i} = - {\text{D}}_{a , e f f} ∇ {C}_{a , i} \text{x} ∈ {Ω}_{a}$$

$${i}_{e} = - {σ}_{e , e f f} ∇ {ϕ}_{e} + {σ}_{e , e f f} \frac{1 - {t}_{+}^{0}}{F} \frac{2 R T}{{C}_{e , i}} ∇ {C}_{e , i} \text{x} ∈ {Ω}_{e}$$

$${\text{N}}_{e} = - {\text{D}}_{e , e f f} ∇ {C}_{e , i} + \frac{{i}_{e} {t}_{+}^{0}}{F} \text{x} ∈ {Ω}_{e}$$

Ωₐ and Ωₑ respectively representing regions of the lithium-ion battery are defined as shown in FIG. 4.

An advection term of a lithium ion flux of the electrolyte has little effect and may be disregarded. It is evident that the flux is 0 in a steady-state, and thus, an anion term may be ignored. The Butler-Volmer equation may not be used to calculate a steady-state.

Because a battery is also a part of a closed system of an electric circuit, the sum of an electron flux and an ion flux inside the battery has to match a magnitude of a current applied from the outside. This principle may be expressed as Equation 5 utilizing Equations 1 to 4.

$$\begin{matrix}{\text{i}}_{a p p} = {σ}_{a , i} \left(1 - {ε}_{i}\right) B \frac{\partial {Φ}_{a , i}}{\partial x} + {\text{FD}}_{e} {ε}_{i} {}^{B} \frac{\partial {C}_{e , i}}{\partial x} + {t}_{+}^{0} {σ}_{e} {ε}_{i} {}^{B} \frac{\partial {Φ}_{e , i}}{\partial x} - \\ {\text{t}}_{+}^{0} {σ}_{e} {ε}_{i} {}^{B} \frac{1 + {t}_{+}^{0}}{F} \frac{2 R T}{{C}_{e , i}} \frac{\partial {C}_{e , i}}{\partial x}\end{matrix}$$

When a position x is transformed into dimensionless position coordinates X, Equation 5 may be expressed as Equation 6.

$$\begin{matrix}{\text{i}}_{a p p} L = {σ}_{a , i} {\left(1 - {ε}_{i}\right)}^{B} \frac{\partial {Φ}_{a , i}}{\partial X} + {\text{FD}}_{e} {ε}_{i} {}^{B} \frac{\partial {C}_{e , i}}{\partial X} + {t}_{+}^{0} {σ}_{e} {ε}_{i} {}^{B} \frac{\partial {Φ}_{e , i}}{\partial X} - \\ {t}_{+}^{0} {σ}_{e} {ε}_{i} {}^{B} \frac{1 - {t}_{+}^{0}}{F} \frac{2 R T}{{C}_{e , i}} \frac{\partial {C}_{e , i}}{\partial X}\end{matrix}$$

Referring to Guduru, A., Northrop, P. W., Jain, S., Crothers, A. C., Marchant, T. R., & Subramanian, V. R. Analytical solution for electrolyte concentration distribution in lithium-ion batteries, Journal of Applied Electrochemistry, 42(4), 189-199 (2012), the entire content of which is herein incorporated by reference, a steady-state distribution to a concentration of lithium ions in the electrolyte may be calculated utilizing Equations 7 to 9.

$${C}_{e , p} \left(X\right) = \frac{{\text{i}}_{a p p} \left(1 - {\text{t}}_{+}^{0}\right) {L}^{2}}{{ε}_{p} {\text{D}}_{e} {\text{x}}_{p} F} \left(\frac{{X}^{2}}{2} {ε}_{p}^{1 - B} + Z\right) {C}_{e , 0}$$

$${C}_{e , s} \left(X\right) = \frac{{\text{i}}_{a p p} \left(1 - {\text{t}}_{+}^{0}\right) {L}^{2}}{{ε}_{p} {\text{D}}_{e} {\text{x}}_{p} F} \left(\frac{X p {ε}_{p}}{{ε}_{s}^{B}} + {p}^{2} {ε}_{p} \left(\frac{1}{2 {ε}_{p}^{B}} - \frac{1}{{ε}_{s}^{B}}\right) + Z\right) + {C}_{e , 0}$$

$${\text{C}}_{e , n} \left(X\right) = \frac{{\text{i}}_{a p p} \left(1 - {\text{t}}_{+}^{0}\right) {L}^{2}}{{ε}_{p} {\text{D}}_{e} {\text{x}}_{p} F} \left(\begin{matrix}- \frac{p {ε}_{p}}{\left(1 - q\right) {ε}_{n}^{B}} \left(\frac{{X}^{2}}{2} - X - \frac{{q}^{2}}{2} + q\right) \\ + \frac{{p}^{2} {ε}_{p}^{1 - B}}{2} + \frac{\left(p q - {p}^{2}\right) {ε}_{p}}{{ε}_{s}^{B}} + Z\end{matrix}\right) + {\text{C}}_{e , 0}$$

Equations 7 to 9 need to follow Equation B1 and Conditional Expression 12.

$${\text{C}}_{e , p} \left(p\right) = {\text{C}}_{e , s} \left(p\right) , {\text{C}}_{e , s} \left(q\right) = {\text{C}}_{e , n} \left(q\right)$$

Z is a constant and may be calculated utilizing Equation B2.

$$\text{Z} = \frac{\left(\begin{matrix}- {ε}_{\text{p}}^{2 - \text{B}} {\text{p}}^{3} + 3 {ε}_{\text{s}} {ε}_{\text{p}}^{1 - \text{B}} {\text{p}}^{3} - 3 {ε}_{\text{s}}^{1 - \text{B}} {\text{p}}^{3} {ε}_{\text{p}} + 6 {ε}_{s}^{1 - \text{B}} {\text{p}}^{2} {ε}_{\text{p}} \text{q} \\ - 3 {ε}_{\text{s}} {ε}_{\text{p}}^{1 - \text{B}} {\text{p}}^{2} \text{q} - \text{3p} {ε}_{\text{p}} {ε}_{\text{s}}^{1 - \text{B}} {\text{q}}^{2} + 6 {ε}_{\text{n}} {ε}_{\text{s}}^{- \text{B}} {\text{p}}^{2} \text{q} {ε}_{\text{p}} \\ - 6 \frac{{ε}_{\text{n}}^{2 - \text{B}} \text{p} {ε}_{\text{p}} {\text{q}}^{2}}{\left(1 - \text{q}\right) {ε}_{\text{n}}} + 6 {ε}_{\text{n}} {ε}_{\text{s}}^{- \text{B}} {\text{p}}^{2} {ε}_{\text{p}} + 2 \frac{{ε}_{\text{n}}^{2 - \text{B}} \text{p} {ε}_{\text{p}} {\text{q}}^{3}}{\left(1 - \text{q}\right) {ε}_{\text{n}}} \\ + 3 {ε}_{\text{n}} {ε}_{\text{p}}^{1 - \text{B}} {\text{p}}^{2} \text{q} - \text{6} {ε}_{\text{n}} {ε}_{\text{s}}^{- \text{B}} {\text{p}}^{2} {ε}_{\text{p}} \text{q} - 2 \frac{{ε}_{\text{n}}^{2 - \text{B}} \text{p} {ε}_{\text{p}}}{\left(1 - \text{q}\right) {ε}_{\text{n}}} \\ - 6 {ε}_{\text{n}} {ε}_{\text{s}}^{- \text{B}} \text{p} {ε}_{\text{p}} \text{q + 6} \frac{{ε}_{\text{n}}^{2 - \text{B}} \text{p} {ε}_{\text{p}} \text{q}}{\left(1 - \text{q}\right) {ε}_{\text{n}}} - 3 {ε}_{\text{n}} {ε}_{\text{p}}^{1 - \text{B}} {\text{p}}^{2}\end{matrix}\right)}{6 \left({ε}_{\text{p}} \text{p} - {ε}_{\text{s}} \text{p +} {ε}_{\text{s}} \text{q +} {ε}_{\text{n}} - {ε}_{\text{n}} \text{q}\right)}$$

To simplify the above steady-state, the function fᵢ(X) may be defined as in Equation 10.

$${\text{f}}_{i} \left(\text{X}\right) = \left\{\begin{matrix}p - X , i = p \\ 0 , i = s \\ X - q , i = n\end{matrix}\right)$$

Equations 7 to 9 may be simplified as in Equation 11 and Conditional Expression 12 utilizing Equation 10.

$$\frac{\partial {\text{C}}_{e , i} \left(X\right)}{\partial X} = \frac{{\text{i}}_{a p p} \left(1 - {\text{t}}_{+}^{0}\right) L}{F {\text{D}}_{e} {ε}_{i} {}^{B}} \left(\frac{{\text{l}}_{i} - {\text{f}}_{i} \left(\text{X}\right)}{{\text{l}}_{i}}\right)$$

$${\text{ε}}_{p} {\int }_{0}^{p} {\text{C}}_{e , i} \left(X\right) d X + {\text{ε}}_{s} {\int }_{p}^{q} {\text{C}}_{e , i} \left(X\right) d X + {\text{ε}}_{n} {\int }_{q}^{1} {C}_{e , i} \left(X\right) d X = {\text{C}}_{e , 0}$$

A steady-state of a current in the active material may be generalized by defining a function g that satisfies Conditional Expression 14 as in Equation 13.

$${\text{i}}_{a , i} = {i}_{a p p} \frac{{\text{g}}_{i} \left(\text{X}\right)}{{\text{l}}_{i}}$$

$$0 \leq \frac{{\text{g}}_{i} \left(\text{X}\right)}{{\text{l}}_{i}} \leq 1 , \frac{\partial {g}_{p} \left(X\right)}{\partial X} \leq 0 , \frac{\partial {g}_{n} \left(X\right)}{\partial X} \geq 0$$

A governing equation of Equation 1 may be generalized to Equation 15 and Conditional Expression 16 utilizing Equation 13.

$$\frac{\partial {\text{Φ}}_{a , i} \left(X\right)}{\partial X} = \frac{{\text{i}}_{a p p} L}{{σ}_{a , i} {\left(1 - {\text{ε}}_{i}\right)}^{B}} \left(\frac{{\text{g}}_{i} \left(\text{X}\right)}{{\text{l}}_{i}}\right)$$

$${\text{Φ}}_{a , p} \left(0\right) = {V}_{b a t t e r y} , {\text{Φ}}_{a , n} \left(1\right) = 0 \left[V\right]$$

A steady-state of lithium ions in the electrolyte and a steady-state of a potential in the active material have been previously described. By substituting the aforementioned steady-state into Equation 6, a steady-state of a potential of the electrolyte may be derived as shown in Equation 17 and Conditional Expression 18.

$$\frac{\partial {\text{Φ}}_{e , i} \left(X\right)}{\partial X} = \frac{{\text{i}}_{a p p} L}{{\text{σ}}_{e} {\text{ε}}_{i} {}^{B} {\text{t}}_{+}^{0}} \left(\frac{\left\{{\text{f}}_{i} \left(\text{X}\right) - {\text{g}}_{i} \left(\text{X}\right)\right\} + {\text{t}}_{+}^{0} \left\{{\text{l}}_{i} - {\text{f}}_{i} \left(\text{X}\right)\right\} \left\{1 + \frac{2 {\left(1 - {t}_{+}^{0}\right)}^{2} R T {\text{σ}}_{e}}{{F}^{2} {C}_{e , 0} {D}_{e}}\right\}}{{\text{l}}_{i}}\right)$$

$${\text{Φ}}_{e , n} \left(1\right) = 0 \left[\text{V}\right]$$

A steady-state of the overpotential distribution may be obtained as in Partial Differential Equation 19 by subtracting Equation 17 from Equation 15.

$$\begin{matrix}\frac{\partial {\text{η}}_{i} \left(X\right)}{\partial X} = \frac{\partial {\text{Φ}}_{a , i} \left(X\right) - {\text{Φ}}_{e , i} \left(X\right) - {U}_{i}}{\partial X} \\ = \frac{{\text{i}}_{a p p} L}{{σ}_{a , i} {\left(1 - {ε}_{i}\right)}^{B}} \left(\frac{{\text{g}}_{i} \left(\text{X}\right)}{{\text{l}}_{i}}\right) \\ - \frac{{\text{i}}_{a p p} L}{{σ}_{e} {ε}_{i} {}^{B} {\text{t}}_{+}^{0}} \left(\frac{\left\{{\text{f}}_{i} \left(\text{X}\right) - {\text{g}}_{i} \left(\text{X}\right)\right\} + {\text{t}}_{+}^{0} \left\{{\text{l}}_{i} - {\text{f}}_{i} \left(\text{X}\right)\right\} \left\{1 + \frac{2 {\left(1 - {t}_{+}^{0}\right)}^{2} R T {σ}_{e}}{{F}^{2} {C}_{e , 0} {D}_{e}}\right\}}{{\text{l}}_{i}}\right) - \frac{\partial {U}_{i}}{\partial X}\end{matrix}$$

By substituting Conditional Expressions 12, 16, and 18 into Partial Differential Equation 19, a generalized overpotential distribution may be calculated. A function gᵢ(X) indicating an electron current distribution in the active material utilized in Equation 19 is an unknown function, and thus may be approximated as follows.

$${\text{i}}_{a , p} \left(\text{x}\right) \approx {\text{i}}_{a p p} \frac{{x}_{p} - x}{{x}_{p}} , {\text{i}}_{a , n} \left(\text{x}\right) \approx {\text{i}}_{a p p} \frac{x - {x}_{n}}{1 - {x}_{n}}$$

By substituting Equation 20 into Equation 13, the function gᵢ(X) may be approximated as a function fᵢ (X) as shown in Equation 21.

$${\text{g}}_{i} \left(\text{X}\right) \approx {\text{f}}_{i} \left(\text{X}\right)$$

By applying Approximate Equation 21 to Equation 17, the equation may be simplified as Equation 22.

$$\frac{\partial {\text{Φ}}_{e , i} \left(X\right)}{\partial X} \approx \frac{{\text{i}}_{a p p} L}{{ε}_{i} {}^{B}} \left(\frac{1}{{σ}_{e}} + \frac{2 {\left(1 - {t}_{+}^{0}\right)}^{2} R T}{{F}^{2} {C}_{e , 0} {D}_{e}}\right) \left(\frac{{\text{l}}_{i} - {\text{f}}_{i} \left(\text{X}\right)}{{\text{l}}_{i}}\right)$$

Therefore, an approximate equation for the final steady-state of the overpotential distribution may be expressed as Equation 23.

$$\begin{matrix}\frac{\text{∂} {\text{η}}_{i} \left(X\right)}{\partial X} = \frac{{\text{i}}_{a p p} L}{{\text{σ}}_{a , i} {\left(1 - {\text{ε}}_{i}\right)}^{B}} \left(\frac{{\text{f}}_{i} \left(\text{X}\right)}{{\text{l}}_{i}}\right) - \\ \frac{{\text{i}}_{a p p} L}{{\text{ε}}_{i} {}^{B}} \left(\frac{1}{{σ}_{e}} + \frac{2 {\left(1 - {t}_{+}^{0}\right)}^{2} R T}{{F}^{2} {C}_{e , 0} {D}_{e}}\right) \left(\frac{{\text{l}}_{i} - {\text{f}}_{i} \left(\text{X}\right)}{{\text{l}}_{i}}\right) - \frac{\partial {U}_{i}}{\partial X}\end{matrix}$$

Coefficients of an overpotential expression in Equation 23 may be defined as Equation 24.

$$\begin{matrix}{k}_{a , i} = \frac{L}{{\text{σ}}_{a , i} {\left(1 - {\text{ε}}_{i}\right)}^{B}} , {k}_{e , i} = \\ \frac{L}{{\text{ε}}_{i} {}^{B}} \left(\frac{1}{{σ}_{e}} + \frac{2 {\left(1 - {t}_{+}^{0}\right)}^{2} R T}{{F}^{2} {C}_{e , 0} {D}_{e}}\right)\end{matrix}$$

A steady-state of a potential distribution of the electrolyte and the active materials may be derived, and the derived steady-state satisfies conditions of Equations 25 to 31.

$$0 \leq \frac{1}{{\text{i}}_{a p p}} \frac{\partial {\text{Φ}}_{a , i} \left(X\right)}{\partial X} = \frac{L}{{\text{σ}}_{a , i} {\left(1 - {\text{ε}}_{i}\right)}^{B}} \left(\frac{{\text{g}}_{i} \left(\text{X}\right)}{{\text{l}}_{i}}\right) \leq \frac{L}{{\text{σ}}_{a , i} {\left(1 - {\text{ε}}_{i}\right)}^{B}}$$

$$\frac{1}{{\text{i}}_{a p p}} \frac{{\partial }^{2} {\text{Φ}}_{a , p} \left(X\right)}{\partial {X}^{2}} = \frac{L}{{\text{σ}}_{a , p} {\left(1 - {\text{ε}}_{p}\right)}^{B} {\text{l}}_{p}} \left(\frac{\partial {\text{g}}_{p} \left(\text{X}\right)}{\partial X}\right) \leq 0$$

$$\begin{matrix}\frac{1}{{\text{i}}_{a p p}} \frac{{\partial }^{2} {\text{Φ}}_{a , n} \left(X\right)}{\partial {X}^{2}} = \\ \frac{L}{{\text{σ}}_{a , n} {\left(1 - {\text{ε}}_{n}\right)}^{B} {\text{l}}_{n}} \left(\frac{\partial {\text{g}}_{n} \left(\text{X}\right)}{\partial X}\right) \geq 0\end{matrix}$$

$$\begin{matrix}0 \leq \frac{1}{{\text{i}}_{a p p}} \frac{\partial {\text{Φ}}_{e , i} \left(X\right)}{\partial X} \approx \frac{L}{{\text{ε}}_{i} {}^{B}} \left(\frac{1}{{σ}_{e}} + \frac{2 {\left(1 - {t}_{+}^{0}\right)}^{2} R T}{{F}^{2} {C}_{e , 0} {D}_{e}}\right) \left(\frac{{\text{l}}_{i} - {\text{f}}_{i} \left(\text{X}\right)}{{\text{l}}_{i}}\right) \leq \\ \frac{L}{{\text{ε}}_{i} {}^{B}} \left(\frac{1}{{σ}_{e}} + \frac{2 {\left(1 - {t}_{+}^{0}\right)}^{2} R T}{{F}^{2} {C}_{e , 0} {D}_{e}}\right)\end{matrix}$$

$$\frac{1}{{\text{i}}_{a p p}} \frac{{\partial }^{2} {\text{Φ}}_{e , p} \left(X\right)}{\partial {X}^{2}} \approx - \frac{L}{{\text{ε}}_{p} {}^{B} {\text{l}}_{p}} \left(\frac{1}{{σ}_{e}} + \frac{2 {\left(1 - {t}_{+}^{0}\right)}^{2} R T}{{F}^{2} {C}_{e , 0} {D}_{e}}\right) \left(\frac{\partial {\text{f}}_{p} \left(\text{X}\right)}{\partial X}\right) \geq 0$$

$$\frac{{\partial }^{2} {\text{Φ}}_{e , s} \left(\text{X}\right)}{\partial {\text{X}}^{2}} \approx 0$$

$$\frac{1}{{i}_{a p p}} \frac{{\partial }^{2} {\text{Φ}}_{e , n} \left(X\right)}{\partial {X}^{2}} \approx - \frac{L}{{\text{ε}}_{n} {}^{B} {\text{l}}_{n}} \left(\frac{1}{{σ}_{e}} + \frac{2 {\left(1 - {t}_{+}^{0}\right)}^{2} R T}{{F}^{2} {C}_{e , 0} {D}_{e}}\right) \left(\frac{\partial {\text{f}}_{n} \left(\text{X}\right)}{\partial X}\right) \leq 0$$

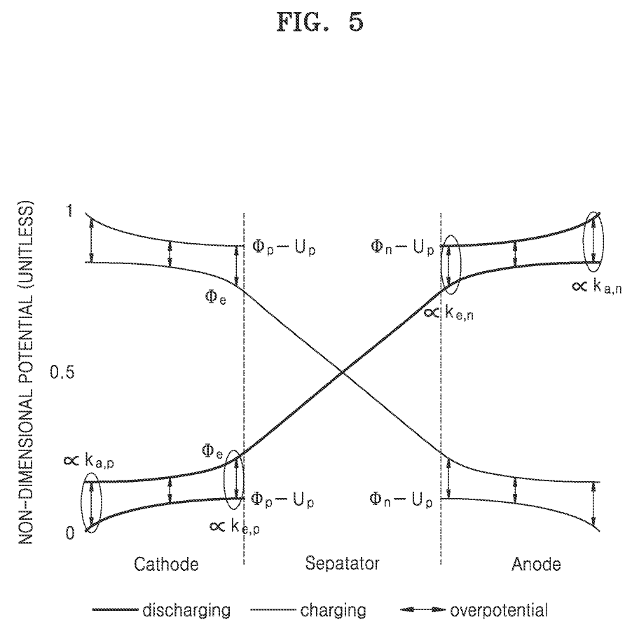

Accordingly, the steady-state may have a distribution as shown in FIG. 5. FIG. 5 illustrates a conceptual diagram of an overpotential distribution according to one or more embodiments of the present disclosure. Referring to FIG. 5, there are four overpotential peak points, and the peak points correspond to k_{a,p}, k_{e,p}, k_{e,n}, k_{a,n} when X = 0, p, q, 1, respectively. Magnitudes of respective peak points are determined by magnitude of four overpotential coefficients.

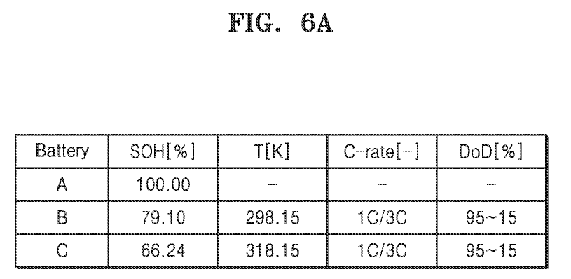

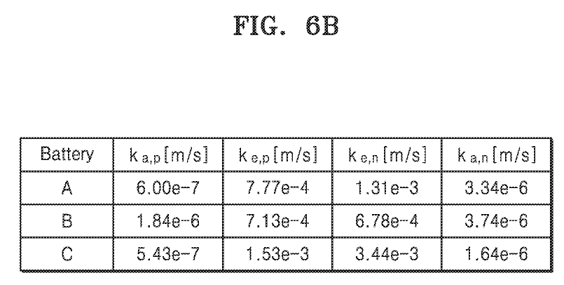

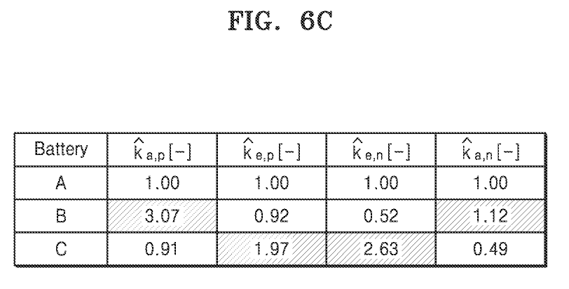

FIG. 6A shows a chart illustrating aging conditions of batteries according to one or more embodiments of the present disclosure.

According to one or more embodiments, aging conditions and states of batteries are as shown in FIG. 6A. Three 37 Ah NMC-carbon lithium-ion batteries were selected, which may be referred to as a battery A, a battery B, and a battery C, respectively. The battery A is a new battery in a beginning-of-life (BOL) state. As shown in FIG. 6A, the battery B and the battery C aged under different conditions. The battery B aged at 25°, and the battery C aged at 45° (shown as 298.15 K and 318.15 K, respectively, in FIG. 6A). A cycle of 1C charge and 3C discharge was repeated between 95% and 15% of state of charge (SOC) in a constant current constant voltage (CCCV) sequence. Both the battery B and the battery C were reduced in state of health (SOH) up to 79% and 66%, respectively, in an end-of-life (EOL) state.

FIG. 6B shows a chart illustrating estimates of overpotential coefficients according to one or more embodiments of the present disclosure.

According to one or more embodiments, each overpotential coefficient may determine a magnitude of a peak point of an overpotential distribution. Therefore, a magnitude of a coefficient is important, but how much a coefficient value of an EOL battery differs from that of a BOL battery is more important. Accordingly, FIG. 6B illustrates overpotential coefficients of the BOL battery (battery A) and EOL batteries (battery B and battery C).

FIG. 6C shows a chart illustrating ratios of overpotential coefficients according to one or more embodiments of the present disclosure.

An overpotential coefficient value of a cathode material in a cathode region of the battery B was approximately three times that of the battery A. As described above, an excessive overpotential in a region between the cathode material and the current collector causes deformation of a cathode crystal structure and a decrease in a contact area. Accordingly, power drop of the battery B is faster than that of the battery C.

In contrast, an overpotential coefficient value of an electrolyte in an anode region of the battery C was 2.63 times greater than that of the battery A. The lithium dendrite growth rate may be calculated by Equation 32.

$${j}_{s} = - \frac{{i}_{0 , s}}{F} \text{exp} \left(- \frac{{α}_{s} F}{R T} η \left(X\right)\right)$$

Referring to Equation 32, a high overpotential coefficient value of the electrolyte in the anode region accelerates growth of lithium dendrites in a region between the anode and the separator, which accelerates damage to the separator. More precisely, the battery C having a lithium dendrite growth rate 1.53 times faster than that of the battery B may be calculated through a ratio of the lithium dendrite growth rate defined in Equation 33.

$$r \left(X\right) = e x p \left(\frac{{α}_{s} F}{R} \left(\frac{{\text{η}}_{M O L} \left(\left(X\right| {i}_{M O L}\right)}{{T}_{M O L}} - \frac{{\text{η}}_{B O L} \left(\left(X\right| {i}_{B O L}\right)}{{T}_{B O L}}\right)\right)$$

This result is consistent with the general findings that a risk of thermal runaway is higher in batteries that aged at high temperature. SEI layer growth and electrolyte decomposition accelerate at high temperature. Both side reactions reduce an effective ionic conductivity of the electrolyte, which results in a high overpotential coefficient of the electrolyte in the anode region. In conclusion, it may be identified that the battery C aged in a direction vulnerable to thermal runaway as the battery C was exposed to high temperature for a long time.

Therefore, the steady-state of the overpotential distribution calculated according to one or more embodiments of the present disclosure may be helpful in quantitatively predicting the risk of thermal runaway in the battery. Also, when a high risk is expected, this may be controlled or reduced by adjusting a charging rate.

Referring to Equation 33 that defines the ratio of the lithium dendrite growth rate, by determining a magnitude of a charging current to constantly maintain

$$\frac{{\text{η}}_{M O L} \left(\left(X\right| {i}_{M O L}\right)}{{T}_{M O L}}$$

at the same level as

$$\frac{{\text{η}}_{B O L} \left(\left(X\right| {i}_{B O L}\right)}{{T}_{B O L}} ,$$

the lithium dendrite growth rate may be controlled or selected to remain at a safe level without receiving positive feedback.

For example, the overpotential coefficient of the electrolyte in the anode region of the battery C is 2.63 times that of the battery A, which indicates that the risk of thermal runaway is very high. Accordingly, when the battery C is charged at a charging rate of 38% of a reference charging rate of the battery A, the battery C may maintain a similar safe range of lithium dendrite growth rates as the battery A. Therefore, the battery charging method according to one or more embodiments of the present disclosure is effective in suppressing or reducing positive feedback related to thermal runaway.

Various embodiments described above are only examples, and do not need to be performed independently of each other. The embodiments described herein may be implemented in combination with each other.

The various embodiments described above may be implemented in the form of a computer program that may be executed through one or more suitable components on a computer, and such a computer program may be recorded in a computer-readable medium. In this case, the computer-readable medium may continuously store a program executable by the computer, or temporarily store the program for execution or downloading. In addition, the computer-readable medium may include one or more suitable recording means or storage means in the form of a single or a combination of several hardware, but is not limited to a medium directly connected to a certain computer system, and may exist distributed on a network. Examples of the computer-readable medium may include a magnetic medium, such as hard disk, a floppy disk and a magnetic tape, an optical recording medium, such as a compact disc read-only memory (CD-ROM) and a digital video disc (DVD), a magneto-optical medium, such as a floppy disk, and a medium including ROM, random-access memory (RAM), flash memory, and/or the like and configured to store program instructions. In addition, other examples of the computer-readable medium may include a recording medium or storage medium managed by an application store that distributes applications, a site that supplies or distributes various other software, or a server.

In the disclosure, the term “...or/er” or “module” may be a hardware component, such as a processor or circuit, and/or a software component that is executed by a hardware component, such as a processor. For example, the “...or/er” or “module” may be implemented by components, such as software components, object-oriented software components, class components, and task components, processes, functions, attributes, procedures, subroutines, segments of program code, drivers, firmware, micro codes, circuits, data, a database, data structures, tables, arrays, and variables.

The above description of the disclosure is provided for illustration, and it will be understood by one of ordinary skill in the art that one or more suitable changes in form and details may be readily made therein without departing from essential features and the scope of the disclosure. Accordingly, it should be understood that the embodiments described above are examples in all aspects and are not for purposes of limitation. For example, each component described as a single type or kind may be implemented in a distributed manner, and similarly, components described as distributed may be implemented in a combined form.

The scope of the disclosure is defined by the appended claims rather than the detailed description, and all changes or modifications within the scope of the appended claims and their equivalents will be construed as being included in the scope of the disclosure.

According to the disclosure, a battery may be prevented or reduced from rapidly aging by estimating a lithium dendrite growth rate according to a charging rate of the battery based on an internal electrochemical parameter of the battery in use, determining a charging current value of the battery based on the lithium dendrite growth rate, and charging the battery with a charging current corresponding to the charging current value.

In the drawings, the relative sizes of elements, layers, and regions may be exaggerated for clarity. As used herein, the singular forms “a,” “an” and “the” are intended to include the plural forms as well, unless the context clearly indicates otherwise. It will be further understood that the terms “comprises,” “comprising,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

The portable device, vehicle, and/or the battery, e.g., a battery controller, and/or any other relevant devices or components according to embodiments of the present invention described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

The circuit of FIG. 1 may be implemented with logic gates or with any other embodiment of a processor. The term “processor” is used herein to include any combination of hardware, firmware, and software, employed to process data or digital signals. Processing unit hardware may include, for example, application specific integrated circuits (ASICs), general purpose or special purpose central processing units (CPUs), digital signal processors (DSPs), graphics processing units (GPUs), and programmable logic devices such as field programmable gate arrays (FPGAs). The sensor and/or any other relevant devices or components according to embodiments of the present invention described herein may be implemented utilizing any suitable hardware, firmware (e.g. an application-specific integrated circuit), software, or a combination of software, firmware, and hardware. For example, the various components of the sensor may be formed on one integrated circuit (IC) chip or on separate IC chips. Further, the various components of the sensor may be implemented on a flexible printed circuit film, a tape carrier package (TCP), a printed circuit board (PCB), or formed on one substrate. Further, the various components of the sensor may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

As used herein, the term “approximate”, “substantially,” “about,” and similar terms are used as terms of approximation and not as terms of degree, and are intended to account for the inherent deviations in measured or calculated values that would be recognized by those of ordinary skill in the art.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the drawings, it will be understood by those of ordinary skill in the art that one or more suitable changes in form and details may be made therein without departing from the spirit and scope of the disclosure as defined by the following claims and equivalents thereof.

What is claimed is:

1. A battery charging method performed by a computing apparatus comprising at least one processor, the battery charging method comprising:
obtaining a reference charging current and a reference lithium dendrite growth rate at the reference charging current;
detecting a battery voltage, a battery current, and a battery temperature of a battery in utilization;
based on the battery current, the battery voltage, and the battery temperature, estimating an internal electrochemical parameter of the battery;
based on the internal electrochemical parameter, calculating an overpotential steady-state distribution of an active material-electrolyte interface according to a charging current of the battery;
based on the overpotential steady-state distribution, calculating a lithium dendrite growth rate according to the charging current of the battery; and
based on the reference lithium dendrite growth rate and the lithium dendrite growth rate according to the charging current, determining a charging current value of the battery.

2. The battery charging method of claim 1, wherein the obtaining of the reference charging current and the reference lithium dendrite growth rate comprises:
obtaining the reference charging current of a new battery;
calculating an overpotential steady-state distribution of an active material-electrolyte interface of the new battery according to the reference charging current; and
based on the overpotential steady-state distribution of the active material-electrolyte interface of the new battery, calculating the reference lithium dendrite growth rate at the reference charging current.

3. The battery charging method of claim 1, wherein the calculating of the overpotential steady-state distribution comprises, based on a physical property value, the internal electrochemical parameter, and the battery temperature of the battery, calculating the overpotential steady-state distribution by utilizing a Differential Equation and a Boundary Condition Equation,
$$\frac{\partial {η}_{i} \left(X\right)}{\partial X} = {i}_{a p p} \left({k}_{a , i} \left(θ\right) \frac{{\text{f}}_{i} \left(\text{X}\right)}{{\text{l}}_{i}} - {\text{k}}_{e , i} \left(θ\right) \frac{{\text{l}}_{i} - {\text{f}}_{i} \left(\text{X}\right)}{{\text{l}}_{i}}\right) - \frac{\partial {U}_{i} \left(X\right)}{\partial X} ,$$
$${Φ}_{n} \left(\text{X=1}\right) = 0 , {\int }_{{Ω}_{i}} \text{sinh} \left(\frac{F}{2 R T} {η}_{i} \left(X\right)\right) d X = \frac{{i}_{a p p}}{2 \text{A} F {\text{l}}_{i} {a}_{i} {i}_{0}} , \text{and}$$
wherein i denotes an internal region of the battery, and when the region i is p, the region i denotes a cathode region, and when the region i is s, the region i denotes a separator region, and when the region i is n, the region i denotes an anode region,
X is a dimensionless position of the battery, and when the position X is 0, the position X denotes a cathode tip of the battery, and when the position X is 1, the position X denotes an anode tip of the battery,
L is a thickness of a battery layer comprising a cathode material, a separator, and an anode material of the battery,
ηᵢ(X) denotes an overpotential between an active material and an electrolyte at the position X of the region i,
iₐₚₚ is a magnitude of a current density applied to a unit area of the battery layer in response to the charging current,
Uᵢ is an open circuit potential of the active material in the region i,
lᵢ is a thickness ratio of the region i to the battery layer,
lₚ is a thickness ratio of the cathode material in the battery layer,
lₙ is a thickness ratio of the anode material in the battery layer, and
lₛ is a thickness ratio of the separator in the battery layer,
fᵢ(X) is a function defined as,
$${\text{f}}_{i} \left(\text{X}\right) = \left\{\begin{matrix}p - X , i = p \\ 0 , i = s \\ X - q , i = n\end{matrix}\right)$$
k_{a,i}(θ) is an overpotential coefficient of the active material in the region i, which determines an open form of an overpotential distribution calculated based on the physical property value, the internal electrochemical parameter, and the battery temperature of the battery,
k_{e,i}(θ) is an overpotential coefficient of the electrolyte in the region i, which determines the open form of the overpotential distribution calculated based on the physical property value, the internal electrochemical parameter, and the battery temperature of the battery,
θ is a battery parameter comprising the physical property value, the internal electrochemical parameter, and the battery temperature of the battery,
ϕₙ(X=1) is a voltage of an anode tip of the battery,
Ωᵢ denotes a range of values of the position X in the region i,
F is the Faraday constant,
R is the gas constant,
T is the battery temperature,
aᵢ is an area per volume of the active material-electrolyte interface of the region i, aₚ is an area per volume of an cathode active material-electrolyte interface, and aₙ is an area per volume of an anode active material-electrolyte interface, and
i₀ is a Butler-Volmer exchange current density between the active material and the electrolyte of the battery.

4. The battery charging method of claim 3, wherein the calculating of the overpotential steady-state distribution by utilzing the Differential Equation and the Boundary Condition Equation comprises:
solving the Differential Equation by utilizing at least one of a finite difference method, a finite element method, or a finite volume method; and
calculating an approximate value of the overpotential between the active material and the electrolyte ηᵢ(X) by utilizing an approximate equation.

5. The battery charging method of claim 3, wherein the overpotential coefficient k_{a,i}(θ) of the active material in the region i is calculated according to an equation,
$${\text{k}}_{a , i} \left(θ\right) = \frac{\text{L}}{{σ}_{a , i} \left(T\right) {\left(1 - {ε}_{i}\right)}^{{B}_{a , i}}} ,$$
wherein the overpotential coefficient k_{e,i}(θ) of the electrolyte in the region i is calculated according to an equation,
$${\text{k}}_{e , i} \left(θ\right) = \frac{\text{L}}{{ε}_{i} {}^{{B}_{e , i}}} \left(\frac{1}{{σ}_{e} \left(T\right)} + \frac{2 {\left(1 - {t}_{+}^{0}\right)}^{2} R T}{{F}^{2} {C}_{e , 0} {D}_{e} \left(T\right)}\right) ,$$
wherein σ_{a,i}(T) is an electrical conductivity of the active material according to the battery temperature,
εᵢ is a porosity of the electrolyte in the region i,
B_{a,i} is a Bruggeman coefficient of the active material in the region i,
B_{e,i} is a Bruggeman coefficient of the electrolyte in the region i,
σₑ(T) is an ionic conductivity of the electrolyte according to the battery temperature,
$${t}_{+}^{0}$$
is a lithium ion transport rate of the electrolyte,
C_{e,0} is an initial concentration of lithium ions in the electrolyte, and
Dₑ(T) is a diffusion coefficient of lithium ions in the electrolyte according to the battery temperature.

6. The battery charging method of claim 5, wherein the internal electrochemical parameter of the battery comprises internal electrochemical parameters comprising an area per volume aₚ of the cathode active material-electrolyte interface, an area per volume aₙ of the anode active material-electrolyte interface, the electrical conductivity σ_{a,i}(T) of the active material according to the battery temperature, the ionic conductivity σₑ(T) of the electrolyte according to the battery temperature, the porosity εᵢ of the electrolyte in the region i, the lithium ion transport rate
$${\text{t}}_{+}^{0}$$
of the electrolyte, the initial concentration C_{e,0} of lithium ions in the electrolyte, and the diffusion coefficient Dₑ(T) of lithium ions in the electrolyte according to the battery temperature, and
the physical property value of the battery comprises physical property values comprising the thickness L of the battery layer, the thickness ratio lₚ of the cathode material, the thickness ratio lₙ of the anode material, the thickness ratio lₛ of the separator, the Bruggeman coefficient B_{a,i} of the active material in the region i, the Bruggeman coefficient B_{e,i} of the electrolyte in the region i, and an area A of the battery layer.

7. The battery charging method of claim 1, wherein the lithium dendrite growth rate is calculated by utilizing an equation based on the overpotential steady-state distribution,
$${j}_{s} = - \frac{{i}_{0 , s}}{F} exp \left(- \frac{{α}_{s} F}{R T} η \left(X\right)\right) ,$$
wherein jₛ is the lithium dendrite growth rate,
i_{0,s} is an exchange current density of a chemical reaction of lithium dendrite growth,
F is the Faraday constant,
R is the gas constant,
T is the battery temperature,
αₛ is a charge transfer coefficient of a lithium dendrite growth reaction,
X is a dimensionless position of the battery, and
η(X) is an overpotential at the position X of the battery and denotes the overpotential steady-state distribution.

8. The battery charging method of claim 1, wherein the charging current value of the battery is determined based on a ratio of the lithium dendrite growth rate according to the charging current with respect to the reference lithium dendrite growth rate defined by an equation,
$$r \left(X\right) = e x p \left(\frac{{α}_{s} F}{R} \left(\frac{{η}_{M O L} \left(X \vert {i}_{M O L}\right)}{{T}_{M O L}} - \frac{{η}_{B O L} \left(X {\vert}_{B O L}\right)}{{T}_{B O L}}\right)\right) ,$$
wherein X is a dimensionless position of the battery,
r(X) is the ratio of the lithium dendrite growth rate at the position X of the battery,
αₛ is a charge transfer coefficient of a lithium dendrite growth reaction,
F is the Faraday constant,
R is the gas constant,
i_{BOL} is a current density of the reference charging current,
i_{MOL} is a current density of the charging current of the battery,
η_{BOL} is an overpotential steady-state distribution of an active material-electrolyte interface of a new battery,
η_{MOL} is the overpotential steady-state distribution of the battery,
T_{BOL} is a reference temperature, and
T_{MOL} is the battery temperature.

9. The battery charging method of claim 8, wherein the charging current value of the battery is determined based on i_{MOL} that satisfies
$$\frac{{η}_{M O L} \left(X \vert {i}_{M O L}\right)}{{T}_{M O L}} = \frac{{η}_{B O L} \left(X \vert {i}_{B O L}\right)}{{T}_{B O L}}$$
.

10. The battery charging method of claim 1, wherein the charging current value of the battery is determined based on a value of the charging current at which the lithium dendrite growth rate according to the charging current is equal to the reference lithium dendrite growth rate.

11. The battery charging method of claim 1, further comprising transmitting the charging current value to a charging apparatus.

12. A computer program stored in a medium for executing the battery charging method of claim 1 on a computing apparatus.

13. A battery pack comprising:
a battery;
a sensor configured to detect a battery current, a battery voltage, and a battery temperature of the battery; and
a battery management unit comprising a memory and at least one processor to manage the battery,
the memory stores a reference lithium dendrite growth rate at a reference charging current, and a physical property value of the battery, and
the processor is configured to,
based on the battery current, the battery voltage, and the battery temperature, estimate an internal electrochemical parameter of the battery,
based on the physical property value and the internal electrochemical parameter of the battery, calculate an overpotential steady-state distribution of an active material-electrolyte interface according to a charging current of the battery,
based on the overpotential steady-state distribution, calculate a lithium dendrite growth rate according to the charging current of the battery, and
based on the reference lithium dendrite growth rate and the lithium dendrite growth rate according to the charging current, determine a charging current value of the battery.

14. A battery charging system performed by a computing apparatus comprising at least one processor, the battery charging system comprising:
means for obtaining a reference charging current and a reference lithium dendrite growth rate at the reference charging current;
means for detecting a battery voltage, a battery current, and a battery temperature of a battery in utilization;
based on the battery current, the battery voltage, and the battery temperature, means for estimating an internal electrochemical parameter of the battery;
based on the internal electrochemical parameter, means for calculating an overpotential steady-state distribution of an active material-electrolyte interface according to a charging current of the battery;
based on the overpotential steady-state distribution, means for calculating a lithium dendrite growth rate according to the charging current of the battery; and
based on the reference lithium dendrite growth rate and the lithium dendrite growth rate according to the charging current, means for determining a charging current value of the battery.
